(19) United States
(12) Patent Application Publication
(10) Pub. No.: US 2007/0164443 A1
(43) Pub. Date: Jul. 19, 2007

(54) Semiconductor array and method for manufacturing a semiconductor array

(75) Inventors: Tobias Florian, Stuttgart (DE); Michael Graf, Leutenbach (DE); Stefan Schwantes, Heilbronn (DE)

Correspondence Address: MCGRATH, GEISSLER, OLDS & RICHARDSON, PLLC, P.O. BOX 1364, FAIRFAX, VA, 22038-1364, US

(73) Assignee: ATMEL Germany GmbH, Heilbronn (DE)

(21) Appl. No.: 11/528,398

(22) Filed: Sep. 28, 2006

(30) Foreign Application Priority Data
Sep. 29, 2005 (DE) 10 2005 046 624.9

(51) Int. Cl. H01L 23/48

(52) U.S. Cl. 257/774

(57) ABSTRACT

Semiconductor array,
with an element region (400),
with a conductive substrate (100),
with a buried insulation layer (200), which isolates the element region (400) from the conductive substrate (100),
with at least one trench (700), which is filled with an insulation material (710) and which isolates at least one element (1000) in the element region (400) from other elements in the element region (400),
with an electrical conductor (750), which is connected conductively to the conductive substrate (100),
wherein the electrical conductor (750) is disposed within the trench (700) isolated by the insulation material (710), and
wherein the trench (700) is formed within a recess (600) in a surface. Furthermore, a method for manufacturing a semiconductor array is provided.

This nonprovisional application claims priority under 35 U.S.C. § 119(a) on German Patent Application No. DE 102005046624, which was filed in Germany on Sep. 28, 2006, and which is herein incorporated by reference.

### BACKGROUND OF THE INVENTION

1. Field of the Invention

The present invention relates to a semiconductor array, a circuit, and a method for manufacturing a semiconductor array.

2. Description of the Background Art

A method for manufacturing a semiconductor element is known from German Patent DE 102 60 616 B3, which corresponds to U.S. Pat. No. 7,005,380. In this case, an element structure is formed on a wafer, whereby the wafer comprises a backside semiconductor substrate, a buried isolation layer, and a top semiconductor layer. An etch stop layer is formed on the wafer. The wafer carries the element structure. A window is formed in the etch stop layer. A dielectric layer is formed on the etch stop layer, which has a window formed therein. This is followed by simultaneous etching of a first contact hole through the dielectric layer and the window down to the backside semiconductor substrate and at least one second contact hole through the dielectric layer down to the element structure.

In the manufacturing of semiconductor elements, SOI wafers or substrates are used to provide superior isolation between adjacent elements in an integrated circuit as compared to elements built into bulk wafers. SOI substrates are silicon wafers with a thin layer of oxide or other insulators buried therein. Elements are built into a thin layer of silicon on top of the buried oxide. The superior isolation thus achieved may eliminate the “latch-up” in CMOS elements (CMOS: Complementary Metal Oxide Semiconductor) and further reduces parasitic capacitances. In addition to the buried oxide layer, shallow trench isolation (STI) is often used to completely isolate transistors or other elements from each other.

Because the backside silicon substrate is completely decoupled from the elements by means of the buried oxide, the potential of the backside substrate tends to float during the operation of the circuit. This may influence the properties of the circuit and reduce operation reliability.

To prevent the backside silicon substrate of the element from floating, special contacts are formed to connect the backside substrate to a metal layer that has a defined potential. An SOI structure is used first that comprises a backside silicon substrate, a buried oxide layer, and a top silicon layer. Transistor structures are formed on top of the SOI structure. The top silicon layer has etched isolation trenches, filled with STI material, to decouple the transistor structures from each other and from other elements.

On top of the top silicon layer, the STI material of the isolation trenches, and the transistor structures, for example, a silicon oxynitride (SiON) layer is deposited that is used in subsequent etching processes as a stop layer. Further, suicides may be formed between this etch stop layer and the top silicon layer.

Then, after the transistor structures and the contact stack of silicon oxynitride (SiON) and tetraethylorthosilicate (TEOS) are formed, a photoresist layer is patterned to provide a backside contact mask having an opening for etching a contact to the backside silicon substrate.

Once the backside contact mask pattern is defined in the photoresist layer, the stack of tetraethylorthosilicate (TEOS), silicon oxynitride (SiON), STI material, and buried oxide is etched down to the backside silicon substrate. A contact hole is formed by this etching step. The STI material of the isolation trench is divided by the formation of the contact hole. The photoresist is now removed by a plasma strip and an additional wet chemical cleaning step.

Once the backside contact hole has been formed, the formation of contacts to connect the transistor structures takes place. This will require another photoresist layer patterning process and a separate etching step.

The aforementioned prior art can be derived, for example, from Unexamined German Patent Application DE 100 54 109 A1, which corresponds to U.S. Pat. No. 6,720,242. In addition, reference is made to U.S. Pat. No. 5,965,917 A, which also deals with the problems of substrate contacting in SOI structures. Two conductive substrate layers, isolated from one another by a buried oxide layer, as conductive rails, each of which are contacted by a deep trench, are known from U.S. Patent Application No. 2003/0094654 A1.

A through-hole plating through a buried insulation layer in a semiconductor substrate is known from European Patent EP 1 120 835 A2. In this case, the through-hole plating connects the source region of a field effect transistor with the semiconductor substrate formed under the buried insulation layer. A method for producing substrate contacts in SOI circuit structures is also known from German Patent DE 103 03 643 B3, which corresponds to U.S. Publication No. 20060160339. In this case, several layer sequences of overlapping metallization layers are formed in the area of the contacting. On the other hand, a contacting of a silicon substrate in a doped region by means of polysilicon is disclosed in WO 02/073667 A2.

Contacting of a substrate region through a dielectric layer is known from U.S. Pat. No. 6,372,562 B1, whereby the contacted substrate region is isolated from another substrate region by a p-n junction poled in the blocking direction. The U.K. Patent Application No. GB 2 346 260 A also discloses a method for forming a contact to a substrate region isolated by a p-n junction in a deep trench of an SOI component. A method for producing a trench in a substrate and its use in smart power technology is known from EP 0 635 884 A1, which corresponds to U.S. Pat. No. 5,445,988. In this case, after reinforcing a trench mask by means of a non-conformally deposited protective layer, the buried insulation layer is etched as far as the silicon substrate in a second trench etching. Another method for producing substrate contacting is known from U.S. Pat. No. 6,632,710 B2.

### SUMMARY OF THE INVENTION

It is therefore and object of the invention to provide a semiconductor array and a method for producing a contacting of a substrate with as improved a process reliability as possible.

Therefore, a semiconductor array is provided. The semiconductor array has an element region, a conductive substrate, and a buried insulation layer, whereby the insulation layer isolates the element region from the conductive substrate. This type of array with a buried insulation layer with use of silicon as the semiconductor material is also called SOI (Silicon On Isolator). The buried insulation layer may have, for example, silicon dioxide.

The semiconductor arrangement has at least one trench filled with an insulation material. This trench isolates at least one element in the element region from other elements in the element region. Elements, such as field-effect transistors, are formed in the element region. For this purpose, the element region preferably has a single-crystal semiconductor material, advantageously silicon with preferably a <100> crystal orientation.

An electrical conductor is conductively connected to the conductive substrate. The electrical conductor is isolated by the insulation material filling the trench and disposed within the trench. The trench is thereby formed as far as a surface. The trench is formed within a recess in the surface. Consequently, both the trench and the recess are adjacent to the element region. The recess in the surface is preferably shallower than the depth of the trench. Furthermore, the recess in the surface is preferably wider than the width of the trench. It is especially preferred for the recess in the surface to have a smaller aspect ratio than the trench. The aspect ratio here is the ratio of the depth of the trench or the recess to its width. The surface is preferably the surface facing away from the substrate of the element region of the semiconductor array.

According to an embodiment, it is provided that the trench is formed not in an edge region of the recess, but in a central area, preferably in the center of the recess.

In fact, it is possible to produce the recess in the surface by a local oxidation (LOCOS; LOCal Oxidation of Silicon), but preferably small structures are made. For this purpose, a development of the invention provides that a shallow trench is provided as the recess. Said shallow trench is preferably filled with dielectric. This is also called STI (Shallow Trench Isolation). Within this shallow trench (STI), the deep trench (Deep Trench Isolation) is formed with a higher aspect ratio. Preferably, both trenches are etched in the semiconductor material of the element region.

According to another aspect, a semiconductor region of the at least one element is formed self-aligned to the recess in the element region. The semiconductor region is, for example, a diffused well with one dopant type. Preferably, the semiconductor region is a semiconductor terminal region formed, for example, by implantation of a dopant. Due to the self-alignment, the semiconductor region is adjacent to the recess.

The contacting of the conductive substrate can thereby be used for different functions. An important function is to change the element parameters of elements disposed on the opposite side of the buried insulation layer by the amount or the time course of the applied substrate potential. In particular, the breakdown voltage of a lateral N-DMOS transistor or a P-DMOS transistor can be improved. Furthermore, a current gain of an NPN-bipolar transistor can be changed, particularly increased, by the amount of an applied substrate potential. It is possible to achieve considerable improvement for positive substrate potentials in this way. Furthermore, the substrate may be used in addition as a line connection to another element or to an integrated circuit contact disposed on the backside. It is also possible by introducing dopants into the substrate, to form semiconductor elements, such as, for example, diodes in the substrate.

The conductive substrate can have a number of substrate regions isolated from one another. These substrate regions may be separated from one another, for example, by deep trench etching. Preferably, these deep trenches are then filled with a dielectric. A separate, fixed or variable potential can thereby be applied to each substrate region independently from one another, so that separate elements in the element region can be operated with different applied substrate potentials.

It is preferably provided here that the substrate regions, isolated from one another, are conductively connected each with at least one electrical conductor disposed in a trench. In addition, a non-contacted substrate region may also be provided.

Advantageous embodiments of the invention provide that the electrical conductor has a highly doped semiconductor material and/or metal and/or silicide.

Regardless of whether the electrical conductor is provided for substrate contacting, in another aspect of the invention, a semiconductor array is provided, which has an element region, a conductive substrate, and a buried insulation layer, whereby the insulation layer isolates the element region from the conductive substrate. The semiconductor array has at least one trench, which is filled with an insulation material and which isolates at least one element in the element region from other elements in the element region. Here, the trench is formed within a recess in a surface of the element region. Also an aspect of the invention is the use of the trench formed in the recess for lateral isolation of a field-effect transistor (DMOS) for high-voltage applications.

Another aspect of the invention is a circuit with an aforementioned semiconductor array. This circuit preferably has a lateral DMOS field-effect transistor. The circuit has means for applying a constant or controllable potential to the electrical conductor. In this case, at least one electrical property of the element depends on the constant or controllable potential. This type of means is, for example, a connection to a supply potential or a connected potential shifter.

Another object forming the basis for the invention is to provide a manufacturing process for a semiconductor array. This object is achieved according to the invention by means of a method with the features of claim 7. Preferred developments of the method are the subject of dependent claims.

Accordingly, a method for manufacturing a semiconductor array is provided. In this method, a conductive substrate, an element region, and an insulation layer, isolating the element region from the conductive substrate, are formed. This type of structure is also called an SOI structure (Silicon-On-Insulator). The element region preferably has a single-crystal semiconductor to form the semiconductor elements. A suitable semiconductor material is, for example, silicon, germanium, or mixed crystals, such as gallium arsenide.

In a process step, a shallow recess is etched in a surface of the element region. The etching occurs preferably with a small depth-to-width aspect ratio for the etched recess (STI). In a later process step, within the shallow recess a trench is etched in the element region as far as the insulation layer through the semiconductor material of the element region. In this case, the etching occurs preferably selectively in regard to oxide layers. Furthermore, for etching the trench, it is preferable to use an etching that enables a high depth-to-width aspect ratio for the etching (Deep Trench).

The deep trench is then etched as far as the conductive substrate. This etching step occurs preferably selectively relative to semiconductor layers of the element region, such as, for example, silicon layers. The walls of the trench are formed next with an insulation material. To form the insulation material, for example, an oxide can be deposited on the wall regions of the trench. Preferably, to form the insulation material, however, a silicon material, adjacent to the trench, of the element region is oxidized. Preferably, in this case, the insulation material is adjacent to the buried insulation layer.

After the etching steps, preferably an electrical conductor is introduced into the trench isolated by the insulation material from the silicon of the element region. In this case, the electrical conductor is connected conductively to the conductive substrate.

According to a further aspect of the invention, it is provided that the shallow recess is filled with dielectric. After the filling with dielectric, a dopant, for example, boron, is introduced for a semiconductor region of the at least one element. For introduction, the dopant can be diffused in and/or implanted, for example. The dielectric in the shallow recess thereby serves as masking to make the semiconductor region of the at least one element self-aligned to the recess in the element region. For self-aligning, the dielectric has, for example, such a thickness that during introduction of the dopant, it is introduced exclusively next to the dielectric in the element region. However, substantially no introduction of the dopant occurs in a region in the vicinity of the deep trench below the dielectric in the shallow recess. A semiconductor region, formed by the introduced dopant and assigned to the at least one element in the element region, is thereby positioned next to the shallow recess. Moreover, no additional mask edge is necessary, so that this can be called self-aligning.

According to an embodiment of the invention, it is provided that for conductive connection of the electrical conductor to the conductive substrate, the insulation material, which covers the bottom of the trench, is removed. For removal, this insulation material covering the bottom is removed substantially in the vertical direction by means of a plasma etching step (ICP, inductive coupled plasma).

In an aspect of the invention, it is provided that a plurality of elements in the element region are formed after the formation of the insulation material. The thermal budget for forming the elements in the element region can therefore occur independent of the formation of the deep trenches. If a polysilicon conductor is introduced into the deep trench, this can also occur advantageously before the formation of the semiconductor elements. The majority of the elements are thereby isolated from one or more substrate regions in the vertical direction by the buried insulator layer. Furthermore, the insulation material in the deep trenches and the insulation material in the shallow recess make possible a lateral isolation of at least two elements.

Preferably to improve the invention further, an isolation trench is etched concurrently with the etching of the trench for receiving the conductor, whereby the isolation trench is completely filled with an insulator and serves exclusively to isolate an element. This makes it possible to reduce the number of necessary etching steps, particularly in the semiconductor material of the element region. Moreover, the positioning accuracy of the deep trench for the conductor for contacting of the substrate and of the additional deep trenches relative to each other is improved.

According to another aspect of the invention, before the trench is etched, a layer sequence comprising a first oxide layer, a polysilicon layer on top of the first oxide layer, and a second oxide layer on top of the polysilicon layer is applied to the element region. The application occurs here at least within the shallow recess. The layer sequence is to protect a surface region outside the deep trench, to be etched, from etching attacks. In an embodiment of this development of the invention, it is provided that the polysilicon layer is oxidized in the step for forming the insulation material and thereby reinforces the first oxide layer in its thickness.

In another aspect of the invention, the second oxide layer is etched concurrently with the buried insulation layer exposed in the trench. The etching is therefore stopped at or in the polysilicon layer and also at or in the semiconductor material of the substrate.

The previously described development variants are especially advantageous both individually and in combination. In this regard, all development variants can be combined with one another. A possible combination is explained in the description of the exemplary embodiment in the figures. However, the possible combination of development variants described therein is not definitive.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 to FIG. 8 illustrate schematic sectional views through a wafer at different process time points in the manufacture of a semiconductor array, and

FIG. 9 illustrates a schematic sectional view of an LDMOS field-effect transistor with a connection to the substrate.

### DETAILED DESCRIPTION

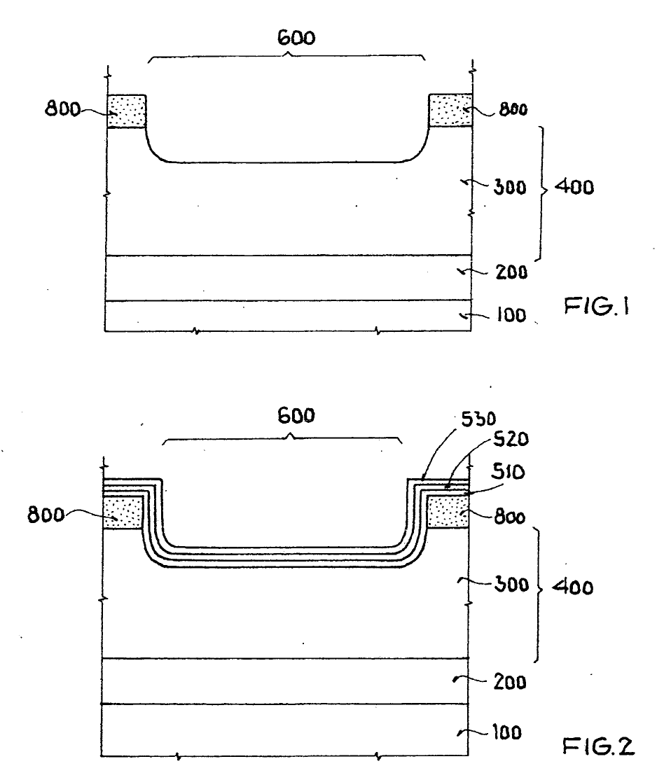

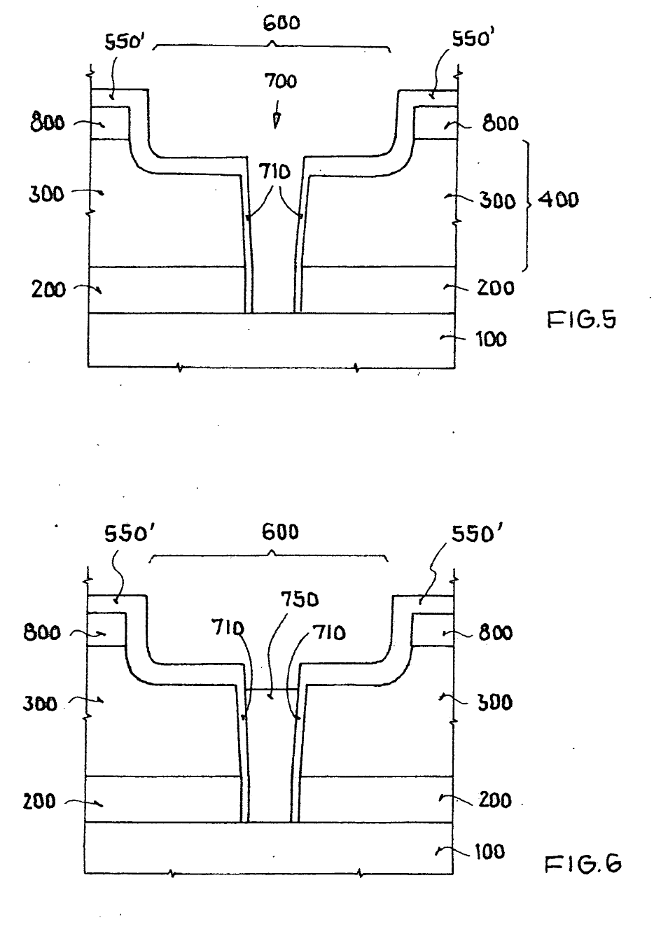

Schematic sectional views through a wafer at different process time points in the manufacture of a semiconductor array are shown in FIGS. 1 through 9. The same structural elements are usually provided with the same reference characters.

An element region 400 of a semiconductor material, in this case silicon 300, a conductive, n-doped silicon substrate 100, and a buried insulation layer 200 are shown in FIG. 1. Insulation layer 200 isolates element region 400 from silicon substrate 100. Insulation layer 200 is a dielectric, for example, made of silicon dioxide (SiO₂). A hard mask 800 of silicon nitride (Si₃N₄) is applied to silicon 300 of element region 400 for masking. A recess 600 is etched in the form of a shallow trench 600 (STI) into the surface of element region 400 made of silicon 300, whereby regions for forming elements are protected by hard mask 800 from the etching attack.

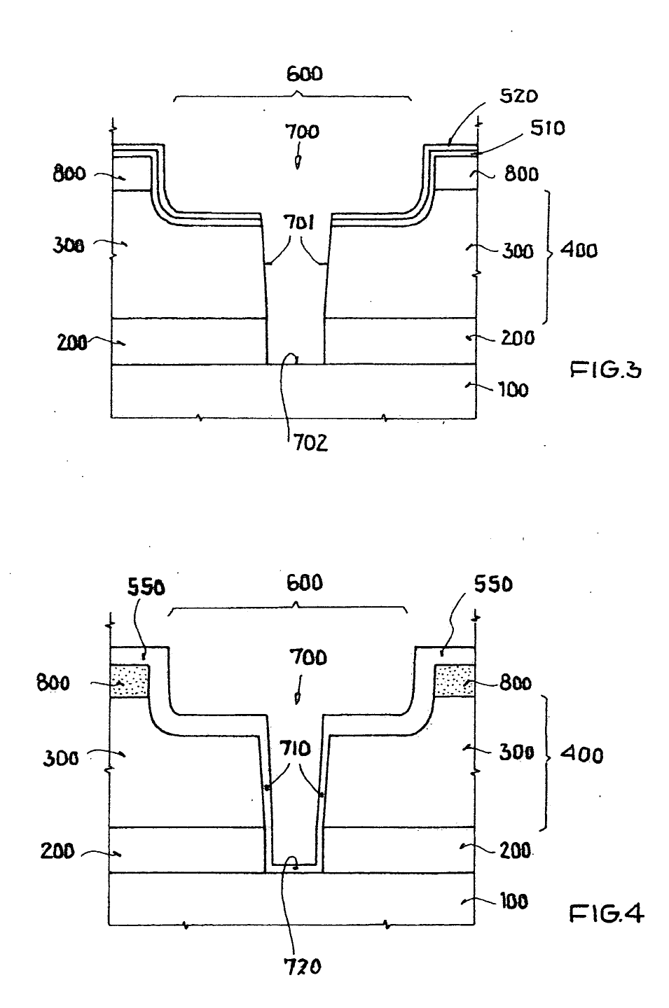

In FIG. 2, a layer sequence comprises a first silicon oxide layer 510 (SiO₂), a layer of polycrystalline silicon 520 (poly-Si), and a second silicon dioxide layer 530 (SiO₂) is applied within etched shallow trench 600 and on hard mask 800. Said layer sequence 510, 520, 530 is also called an OPO layer. Preferably, these layers 510, 520, 530 are deposited successively one after another.

The layer sequence of layers 510, 520, 530 is patterned lithographically by a photoresist and a mask in such a way that a vertical opening is introduced into the layer sequence. A deep trench 700 (Deep Trench) is etched through this vertical opening. This etching is selective in regard to second oxide layer 530 and thereby substantially removes only silicon 300. After this, buried oxide 200 is removed below the etched opening. At the same time, second oxide layer 530 is also removed. FIG. 3 shows the state after etching of buried oxide 200 below the etched opening and the second oxide layer. Deep trench 700 has trench walls 701 and a trench bottom 702.

Subsequently, in the next process step, a thermal oxide of the highest quality possible is produced, preferably with a thickness of 50 nm. In this case, an oxide layer 710 or 720, respectively, is formed at trench walls 701 and on trench bottom 702. This state is shown schematically in FIG. 4. In this case, the silicon material of element region 400 in the wall region and the silicon material of silicon substrate 100 are converted to silicon dioxide. Furthermore, polysilicon layer 520 is also converted to silicon dioxide, so that together with first oxide layer 510, a thicker silicon dioxide top layer 550 is formed at least within shallow recess 600 on element region 400.

In the next process step, oxide 720 on the bottom of deep trench 700 is etched off by anisotropic etching. This process state is shown in FIG. 5. In this case, silicon dioxide top layer 550′ is accordingly thinned, but not totally removed.

Then, conformal polysilicon 750 or amorphous silicon 750 is deposited on the wafer and etched back to the entrance of the deep trench 700. Polysilicon 750 can either be already doped during the deposition or in the later contact opening by implantation. The doping type advantageously corresponds to that of silicon substrate 100.

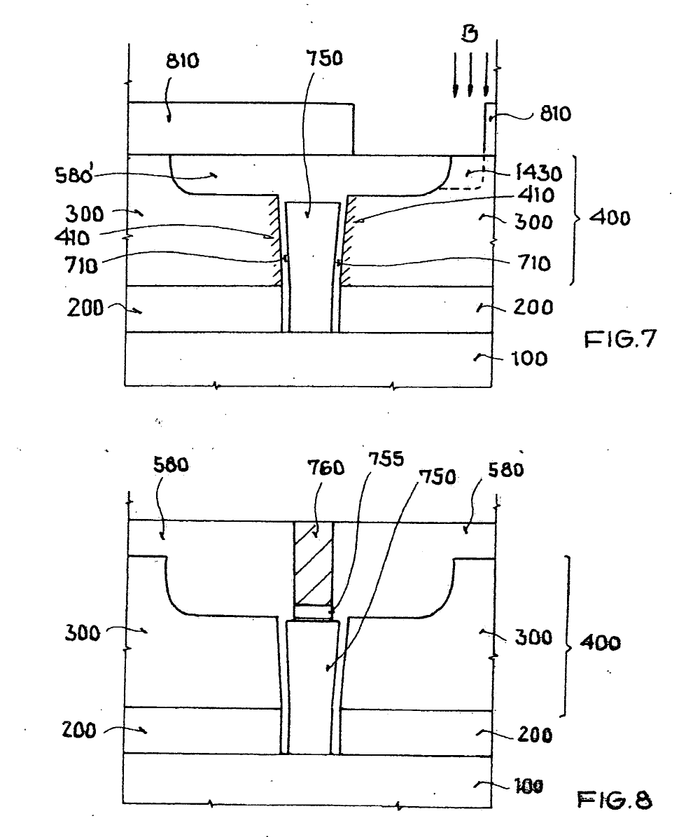

Next, to achieve the process state according to FIG. 7, shallow trench 600 is filled with oxide 580′, the hard mask (800) is removed, and the wafer surface is planarized, for example, by means of chemical mechanical polishing (CMP). The next process steps are used to produce the semiconductor elements in element region 400. In this case, a resist 810 is applied and patterned photolithographically as implantation mask 810. In so doing, oxide 580′ in shallow trench 600 also forms a mask, which protects semiconductor material 300 of element region 400 in the area below oxide 580′ from the dopant to be implanted.

The masking by oxide 580′ has the effect that a semiconductor region 1430 of an associated element 1000 (see FIG. 9) is formed adjacent to oxide 580′ in shallow trench 600. Semiconductor region 1430 is, in addition, oriented by the masking self-aligning to shallow trench 600. In the exemplary embodiment of FIG. 7, boron B is implanted as the dopant, whereby semiconductor region 1430, for example, is formed as a p-doped semiconductor terminal region with a high dopant concentration.

In an area of element region 400, which is laterally adjacent to shallow trench 600, the density of the crystal defects in the element region is much lower than in a border area 410 of element region 400, which is laterally adjacent to deep trench 700. Border area 410, adjacent to oxide 710, of element region 400 can have a high density of imperfections in the single-crystal crystal lattice. The arrangement of the deep trench within the shallow trench by the self-aligning of semiconductor region 1430 and thereby by the self-aligning of element 1000 makes possible a guaranteed distance between the deep trench and active regions of element 1000, so that process variations can be reduced. As another possible advantage of the formation of a deep trench 700 within shallow trench 600, element 1000 can have an improved breakthrough voltage. Advantageously, the width of shallow trench 600 can be matched to a possible misalignment of the mask for etching of deep trench 700.

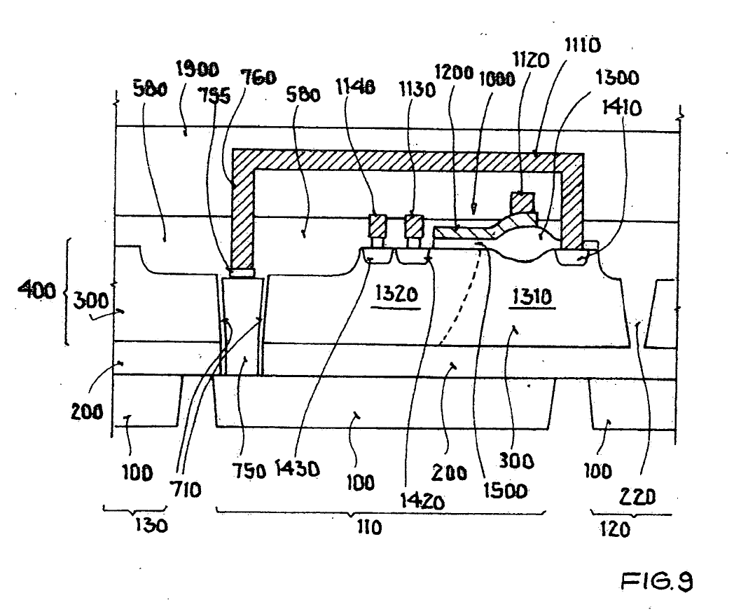

The contacting of silicon substrate 100 through deep trench 700 (contact trench) is continued only after all elements are finished. For contacting polysilicon filling 750, oxide 580 in shallow trench 600 is removed above polysilicon 750 in a lithographic masked etching step. The etched oxide opening is now filled with a diffusion barrier 755, for example, made of a silicide, and with a metal 760, for example, tungsten. This process state is shown in FIG. 8.

FIG. 9 shows a schematic sectional view through a wafer with a power element 1000, which is formed in element region 400, and a contacting of silicon substrate 100. Silicon substrate 100 is thereby divided into several substrate regions 110, 120, 130 by etched trenches. A substrate region 110 is thereby formed below power element 1000. Power element 1000 is isolated by the deep trench (700), filled with polysilicon 750, and by at least one other trench isolation 220 from neighboring elements (not shown in FIG. 9) by a dielectric 710, 220, particularly of silicon dioxide.

In the exemplary embodiment of FIG. 9, power element 1000 is an N-DMOS field-effect transistor 1000. This has an n-doped drain semiconductor region 1410, an N-well 1310, formed as a drift zone, a P-well 1320, formed as a body semiconductor region, an n-doped source semiconductor region 1420, and a p-doped body terminal semiconductor region 1430. Furthermore, N-DMOS field-effect transistor 1000 has a field oxide 1300 and a gate oxide 1500 with polysilicon gate electrode 1200 disposed thereon.

Drain semiconductor region 1410, gate electrode 1200, source semiconductor region 1420, and body terminal semiconductor region 1430 are each conductively connected to a metal trace 1110, 1120, 1130, and 1140. In the exemplary embodiment of FIG. 9, substrate region 110 is connected via polysilicon 750, diffusion barrier 755, metal 760, and trace 1110 to drain semiconductor region 1410, so that substrate region 110 substantially has the same potential as drain semiconductor region 1410. The wafer is protected by a boron-phosphorus-silicate glass 1900 from outside influences.

Alternatively to FIG. 9, substrate region 110 can also be connected to another element for controlling the potential of substrate region 110. Another possibility is to connect substrate region 110 to a fixed potential, for example, by means of a voltage divider comprising two capacitors.

The invention is understandably not limited to the shown exemplary embodiment, but also comprises embodiment variants that are not shown. For example, the aspect ratio for shallow trench 600 and deep trench 700, as shown in the exemplary embodiment, can also be made different. It is also possible to use a metallic substrate. The invention is also not limited to power element 1000 shown in FIG. 2, but protects, for example, every semiconductor array with any elements that make use of the trench 700 within the recess 600.

List of Reference Characters

100 Silicon substrate
110, 120, 130 Substrate region
200 Buried insulation layer, SiO₂
220 Deep trench filled with dielectric
300 Single-crystal silicon crystal
400 Element region
410 Region with crystal imperfections
510 First oxide layer
520 Polysilicon layer
530 Second oxide layer
550, 550′ Oxide layer
580, 580′ Dielectric, silicon dioxide
600 Shallow, etched trench
700 Deep trench, etched
701 Wall of the deep trench
702 Bottom of the deep trench
710 Insulation material, silicon dioxide
720 Insulation material, silicon dioxide
750 Doped polysilicon filling
755 Diffusion barrier, silicide
760 Metal, tungsten, aluminum
800 Hard mask, Si₃N₄
810 Resist, photoresist masking
1000 Element, N-DMOS field-effect transistor
1110, 1120, Metallization, trace
1130, 1140
1200 Gate electrode, polycrystalline silicon
1300 Field oxide
1320 P-well, body
1410 Drain semiconductor region
1420 Source semiconductor region
1430 Body terminal semiconductor region
1500 Gate oxide
1900 Boron-phosphorus-silicate glass
B Dopant (boron) of an implantation

What is claimed is:

1. A semiconductor array comprising:
an element region;
a conductive substrate;
a buried insulation layer that isolates the element region from the conductive substrate;
at least one trench that is filled with an insulation material and that isolates at least one element in the element region from other elements in the element region; and
an electrical conductor that is connected conductively to the conductive substrates,
wherein the electrical conductor is disposed within the trench isolated by the insulation material, and
wherein the trench is formed within a recess in a surface.

2. Semiconductor element according to claim 1, wherein the recess is a shallow trench (STI).

3. Semiconductor array according to claim 1, wherein the recess is filled with dielectric.

4. Semiconductor array according to claim 1, wherein a semiconductor region is formed self-aligned to the recess in the element region.

5. Semiconductor array according to claim 1, wherein the conductive substrate has a number of substrate regions isolated from one another, and wherein the substrate regions isolated from one another, are each connected conductively to at least one electrical conductor disposed in a trench.

6. A circuit comprising a semiconductor array according to claim 1, the circuit being configured to apply a constant or controllable potential to the electrical conductor, whereby at least one electrical property of the at least one element depends on the constant or controllable potential.

7. A method for manufacturing a semiconductor array, the method comprising:
forming a conductive substrate, an element region, and an insulation layer, isolating the element region from the conductive substrate;
etching a shallow recess in a surface of the element region;
etching a trench within the shallow recess in the element region as far as the insulation layer;
etching the trench further as far as the conductive substrate;
forming the walls of the trench with an insulation material; and
introducing an electrical conductor into the trench and connected conductively to the conductive substrate.

8. Method according to claim 7, wherein the shallow recess is filled with dielectric, and wherein a dopant (B) is introduced for a semiconductor region of the at least one element, whereby the dielectric in the shallow recess serves as a mask, to form the semiconductor region of the at least one element self-aligned to the shallow recess in the element region.

9. Method according to claim 7, wherein for conductive connection of the electrical conductor to the conductive substrate, the insulation material, which covers the bottom of the trench, is removed.

10. Method according to claim 7, wherein to form the insulation material a silicon region, adjacent to the trench, of the element region is oxidized.

11. Method according to claim 7, wherein before the trench is etched, a layer sequence comprising a first oxide layer, a polysilicon layer on top of the first oxide layer, and a second oxide layer on top of the polysilicon layer is applied to the element region within the shallow recess.

12. Method according to claim 11, wherein the polysilicon layer is oxidized in the step for forming the insulation material, and/or wherein the second oxide layer is etched concurrently with the buried insulation layer exposed in the trench.
